(19) United States
(12) Patent Application Publication
(10) Pub. No.: US 2025/0174956 A1
(43) Pub. Date: May 29, 2025

(54) LASER SYSTEM AND METHOD FOR PROVIDING A PULSED LASER BEAM INTENDED FOR INTERACTION WITH A TARGET MATERIAL

(71) Applicant: TRUMPF Laser GmbH, Schramberg (DE)

(72) Inventors: Jonathan Brons, Aichhalden (DE); Sven-Silvius Schad, Rottweil (DE); Michael Harteker, Rottweil (DE); Stephan Häfner, Donaueschingen (DE); Dirk Sutter, Rottweil (DE)

(21) Appl. No.: 19/040,879

(22) Filed: Jan. 30, 2025

Related U.S. Application Data
(63) Continuation of application No. PCT/EP2023/071597, filed on Aug. 3, 2023.

(30) Foreign Application Priority Data
Aug. 4, 2022 (DE) 102022119609.7

(51) Int. Cl. H01S 3/00; G03F 7/00

(52) U.S. Cl. CPC H01S 3/0071; H01S 3/0014; G03F 7/70025; G03F 7/70041; G03F 7/7055

(57) ABSTRACT

A laser system includes a beam deflection unit, a control unit, a laser beam source for providing a pulsed input laser beam for coupling into the beam deflection unit, and a target area for arranging a target material. The control unit is configured to control and/or regulate a position of a pulsed laser beam emerging from the beam deflection unit by actuating the beam deflection unit. The control unit has a first operating mode, in which the position of the pulsed laser beam is selected so that it is directed onto the target area, and a second operating mode, in which the position of the pulsed laser beam is selected so that it misses the target area. Pulsed laser beams provided in the second operating mode are positioned symmetrically in a chronological and/or spatial average with respect to the pulsed laser beams formed in the first operating mode.

### CROSS REFERENCE TO RELATED APPLICATIONS

This application is a continuation of International Application No. PCT/EP2023/071597 (WO 2024/028461 A1), filed on Aug. 3, 2023, and claims benefit to German Patent Application No. DE 10 2022 119 609.7, filed on Aug. 4, 2022. The aforementioned applications are hereby incorporated by reference herein.

### FIELD

Embodiments of the present invention relate to a laser system and a method for providing a pulsed laser beam intended for interaction with a target material.

### BACKGROUND

An EUV radiation generating device is known from WO 2014/044392 A1, comprising a vacuum chamber in which a target material is arrangeable at a target position for generating EUV radiation, and a radiation guidance chamber for guiding a laser beam from a driver laser unit in the direction toward the target position. An intermediate chamber, which is attached between the vacuum chamber and the beam guidance chamber, a first window, which closes the intermediate chamber gas-tight, for the entry of the laser beam from the beam guidance chamber, and a second window, which closes the intermediate chamber gas-tight, for the exit of the laser beam into the vacuum chamber, are provided.

A method for laser material processing by means of a processing laser beam is known from DE 10 2020 200 798 A1, wherein a first laser beam, which is coupled at least into a first fibre core of an optical multicore fibre, and/or a second laser beam, which is coupled at least into a second fibre core of the multicore fibre, are generated from an input laser beam. The first and the second laser beams are decoupled alone or together as a processing laser beam from the multicore fibre and the ratio of the laser power between the first and the second laser beam is changed at a modulation frequency between 1 Hz and 100 kHz.

### SUMMARY

Embodiments of the present invention provide a laser system for providing a pulsed laser beam intended for interaction with a target material. The laser system includes a beam deflection unit, a control unit assigned to the beam deflection unit, a laser beam source for providing a pulsed input laser beam for coupling into the beam deflection unit, and a target area for arranging the target material. The pulsed input laser beam is capable of being deflected and/or split by the beam deflection unit. At least one pulsed laser beam emerging from the beam deflection unit is provided by the beam deflection unit based on the pulsed input laser beam. The control unit is configured to control and/or regulate a position of the at least one pulsed laser beam relative to the target area by actuating the beam deflection unit. The control unit has a first operating mode, in which the position of the at least one pulsed laser beam is selected so that the at least one pulsed laser beam is directed onto the target area, in order to interact with the target material arranged in the target area. The control unit has a second operating mode, in which the position of the at least one pulsed laser beam is selected so that the at least one pulsed laser beam misses the target area. Pulsed laser beams provided in the second operating mode are positioned symmetrically in a chronological and/or spatial average with respect to the pulsed laser beams formed in the first operating mode.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows an exemplary embodiment of a laser system;

FIG. 2 shows a cross section of provided pulsed laser beams, wherein a positioning of the pulsed laser beams relative to a target material in different operating modes is shown, according to some embodiments;

FIG. 3 shows a representation of different frequencies of a control voltage, which is used to actuate a beam deflection unit of the laser system, wherein a power is plotted as a function of the respective frequency, according to some embodiments;

FIG. 4 shows a cross section of provided laser beams, wherein respective beam cross sections of the laser beams overlap and form a focus zone, according to some embodiments;

FIG. 5 shows a first example of a positioning of provided pulsed laser beams as a function of time relative to the target material according to some embodiments; and

FIG. 6 shows a second example of a positioning of provided pulsed laser beams as a function of time relative to the target material according to some embodiments.

### DETAILED DESCRIPTION

Embodiments of the present invention provide a laser system and method, by means of which a pulsed laser beam intended for interaction with the target material can be generated with a high average power and at the same time an ability to control the interaction of the laser pulses of the pulsed laser beam with the target material is enabled.

According to embodiments of the invention, the laser system comprises a beam deflection unit, a control unit assigned to the beam deflection unit, a laser beam source for providing a pulsed input laser beam for coupling into the beam deflection unit, and a target area for arranging the target material, wherein the pulsed input laser beam can be deflected and/or split by means of the beam deflection unit and at least one pulsed laser beam emerging from the beam deflection unit is provided by means of the beam deflection unit based on the pulsed input laser beam, wherein the control unit is configured to control and/or regulate a position of the at least one pulsed laser beam relative to the target area by actuating the beam deflection unit, wherein the control unit has a first operating mode, in which the position of the at least one pulsed laser beam is selected so that it is directed onto the target area, in order to interact with a target material arranged in the target area, and wherein the control unit has a second operating mode, in which the position of the at least one pulsed laser beam is selected so that it misses the target area.

By selecting the first operating mode and the second operating mode, it can be selected whether or not the pulsed laser beam strikes the target material arranged in the target area, i.e. whether or not laser pulses assigned to the pulsed laser beam interact with the target material. In this way, for example, generation of secondary radiation and in particular an average dose and/or intensity of generated secondary radiation can be controlled in a technically simple manner.

In the solution according to embodiments of the invention, the pulsed laser beam is deflected and/or aligned in the first operating mode so that it strikes the target material arranged in the target area, and in the second operating mode it is deflected and/or aligned so that it does not strike the target material, i.e. the pulsed laser beam is in this case “guided past” the target material or “fired past” it. No technical intervention on the laser beam source itself is therefore necessary in order to supervise the interaction between the existing pulsed laser beam and the target material. In particular, no chronological supervision of laser pulses of the input laser beam or pulsed laser beam provided by means of the laser beam source is necessary in order to deliberately prevent the interaction with the target material.

By means of the provided beam deflection unit, the position and/or orientation and/or alignment of the at least one pulsed laser beam relative to the target area and the target material arranged therein can be controlled in a time-dependent manner in a technically simple way by actuation via the control unit. Furthermore, possible splitting of the input laser beam can thus be controlled in order to provide either one or multiple pulsed laser beams emerging from the beam deflection unit.

In particular, the first operating mode and the second operating mode can be set and/or selected on the control unit. It can be provided that the control unit has an input for receiving a control signal, wherein a selection of the first operating mode or the second operating mode is carried out by means of the control signal.

The position of the at least one pulsed laser beam relative to the target area is in particular to be understood as a position of a focused area and/or a focused cross section of the at least one pulsed laser beam relative to the target area.

The pulsed laser beam that can be provided is suitable and/or configured in particular for interaction with the target material.

In particular, it can be provided that the laser system is suitable and/or configured for generating secondary radiation by interaction of the pulsed laser beam with the target material. It can then be provided in particular that the pulsed laser beam is directed onto the target material in the first operating mode, so that laser pulses of the pulsed laser beam interact with the target material and secondary radiation is thus generated.

Alternatively or additionally, the laser system can be suitable and/or configured for preparing and/or preprocessing the target material by interaction of the pulsed laser beam with the target material. In particular, the target material is then, in the first operating mode, brought into a specific form and/or into a specific state by interaction of laser pulses of the pulsed laser beam, which thereafter efficiently enables generation of secondary radiation by interaction with further laser pulses. For example, the preparation of the target material is carried out using laser pulses of a first laser beam source and the following generation of secondary radiation is then carried out by interaction with further laser pulses of a second laser beam source. The second laser beam source then in particular has a higher average power than the first laser beam source.

Furthermore, the laser system can also be used for diagnosis of the quality of the mentioned preparation and/or preprocessing of the target material.

The statement that the at least one pulsed laser beam misses the target area and/or the target material arranged therein in the second operating mode is to be understood to mean that the at least one pulsed laser beam does not or does not significantly interact with the target material so that, for example, depending on the application of the laser system, no secondary radiation or secondary radiation below a threshold intensity is generated or no or no sufficient preparation of the target material takes place.

The statement that the at least one pulsed laser beam strikes the target area and/or the target material arranged therein in the first operating mode is to be understood to mean that the at least one pulsed laser beam interacts with the target material so that, for example, depending on the application of the laser system, secondary radiation above the threshold intensity is generated or preparation or sufficient preparation of the target material takes place.

In particular, the control unit has no further operating state except for the first operating state and the second operating state (except for a deactivated state).

The laser beam source in particular comprises a seed laser, such as a diode laser.

In particular, the laser beam source comprises a laser amplifier and/or a chain of laser amplifiers. The laser amplifier or amplifiers are preferably Yb-doped or Nd-doped. For example, Yb: glass, Yb: YAG, or Nd: YAG amplifiers are used as laser amplifiers. In particular, the laser amplifiers used can be embodied in fibre, rod, slab, or disc geometry.

In the first operating mode, precisely one pulsed laser beam emerging from the beam deflection unit is preferably provided, which is directed onto the target area and/or the target material. In particular, in this case multiple pulsed laser beams emerging from the beam deflection unit are not provided simultaneously, but rather the precisely one pulsed laser beam is provided at a specific time.

In particular, it can be provided that, in the second operating mode, precisely one pulsed laser beam emerging from the beam deflection unit is provided, which misses the target area. In particular, in this case multiple pulsed laser beams emerging from the beam deflection unit are not provided simultaneously, but rather the precisely one pulsed laser beam is provided at a specific time.

It can be advantageous if the position of the precisely one pulsed laser beam is deflected, in chronologically successive second operating modes, alternately with respect to the target area toward a first side and toward a second side opposite to the first side. In the chronological average, for example, a symmetrical arrangement of the pulsed laser beams provided in successive second operating modes with respect to the pulsed laser beam provided in the first operating mode can thus be provided. A simplified and low-interference stabilization of orientation and/or positioning of pulsed laser beams emerging from the beam deflection unit can thus in turn be implemented.

For the same reason, it can be advantageous if the position of the precisely one pulsed laser beam is deflected, in chronologically successive second operating modes, alternately with respect to the target area in a first direction and in a second direction opposite to the first direction.

Chronologically successive second operating modes are in particular to be understood to mean that the second operating mode is initially selected at a certain time and then is selected again at a later time, wherein the first operating mode is selected for a specific period of time between these two times. Then, for example, a sequence of first operating mode (time t₁)—second operating mode (time t₂)—first operating mode (time t₃)—second operating mode (time t₄), etc. results, wherein t₁<t₂<t₃<t₄. Successive second operating modes are to be understood, for example, as those at the times t₂ and t₄, i.e. two second operating modes selected in chronological succession.

It can be favourable if, in the second operating mode, two or more pulsed laser beams from the beam deflection unit are provided, which emerge simultaneously from the beam deflection unit. A symmetrical arrangement of the pulsed laser beams provided in the second operating mode with respect to the pulsed laser beam provided in the first operating mode can thus be achieved, for example, in the spatial average. A simplified and low-interference stabilization of orientation and/or positioning of pulsed laser beams emerging from the beam deflection unit can thus in turn be implemented.

For example, the pulsed laser beams provided in the second operating mode are then spatially positioned and/or oriented symmetrically with respect to the pulsed laser beam provided in the first operating mode. For example, one of the pulsed laser beams provided in the second operating mode is deflected toward a first side and/or first direction with respect to the target area and a further one of the pulsed laser beams provided in the second operating mode is deflected toward a second side opposite to the first side and/or a second direction opposite to the first direction with respect to the target area. In particular, a simplified and low-interference stabilization of orientation and/or positioning of pulsed laser beams emerging from the beam deflection unit can thus be implemented. In particular, advantages result in this way upon use of a beam tracker for stabilization, wherein faulty feedback signals can be reduced or avoided in this case, for example.

For the same reason, it can be advantageous if pulsed laser beams provided in the second operating mode are positioned symmetrically in the chronological and/or spatial average with respect to the pulsed laser beams formed in the first operating mode. For example, plane symmetry and/or point symmetry of pulsed laser beams provided in the second operating mode is present with point symmetry with respect to the pulsed laser beams provided in the first operating mode.

In particular, it can be provided that a position of a centre point of a beam cross section of the at least one pulsed laser beam in the target area in the first operating mode is spaced apart from the position of the centre point of the at least one pulsed laser beam in the second operating mode by at least one diameter of the beam cross section. In the case of multiple pulsed laser beams present simultaneously, the respective positions of the centre points of all pulsed laser beams present in the first operating mode are spaced apart from the respective positions of the centre points of all pulsed laser beams present in the second operating mode by at least a diameter of the beam cross section of the respective pulsed laser beams.

In particular, it can be provided that the beam deflection unit comprises an acoustooptical deflector and/or an acoustooptical modulator or is designed as an acoustooptical deflector or acoustooptical modulator. The position of the at least one pulsed laser beam can thus be varied relative to the target area with a high chronological dynamic.

The at least one pulsed laser beam is to be understood in the scope of the present documents, in principle, as a used laser beam which is provided by deflection and/or splitting of the input laser beam by means of the beam deflection unit and, depending on the positioning and/or splitting according to the selected operating mode, can be used for interaction with the target material which is sufficient according to the intended application. In the case of an acoustooptical deflector or modulator, in particular the first order of diffraction is used as the used laser beam. Other orders of diffraction are not used and are therefore not included by the designation “pulsed laser beam”.

In particular, the beam deflection unit is actuated by means of the control unit in the first operating mode using a control voltage which has a constant carrier frequency. In particular, a frequency spectrum of the control voltage then has the carrier frequency as the only frequency. In particular, a single pulsed laser beam thus emerges from the beam deflection unit, which is directed onto the target area.

For example, the beam deflection unit is actuated by means of the control unit in the second operating mode using a control voltage which has a frequency reduced in relation to the carrier frequency or a frequency increased in relation to the carrier frequency. In particular, an idealized frequency spectrum of the control voltage then has a single frequency, which is the reduced or increased frequency. In particular, a single pulsed laser beam thus emerges from the beam deflection unit, which is deflected such that it misses the target area.

For example, the increased frequency and the reduced frequency are located symmetrically with respect to the carrier frequency.

For example, the beam deflection unit is actuated by means of the control unit in the second operating mode using a control voltage which has a superposition of two or more frequencies, wherein these frequencies are different from the carrier frequency. In particular, a frequency spectrum of the control voltage then has two or more frequencies different from the carrier frequency, but in particular not the carrier frequency itself. In particular, two or more pulsed laser beams thus emerge simultaneously from the beam deflection unit, which are deflected such that they miss the target area.

For example, the two or more frequencies are located symmetrically with respect to the carrier frequency.

It can be provided that the beam deflection unit is actuated by means of the control unit in the second operating mode using a control voltage which has a beat of signals having a frequency reduced in relation to the carrier frequency and a frequency increased in relation to the carrier frequency.

In particular, it can be provided that, in the first operating mode, laser pulses of the at least one pulsed laser beam are introduced into the target area such that they are chronologically synchronized with a target material introduced into the target area, so that, in the first operating mode, an interaction of one or more laser pulses with the target material takes place in the target area. For example, a coupling of target material into the target area can be chronologically slightly irregular or subject to error, wherein a corresponding jitter can be, for example, +/−1 μs. It can be ensured by the mentioned synchronization in the first operating mode that an interaction of laser pulses of the pulsed laser beam with the target material which is sufficient according to the application actually takes place.

For example, laser pulses of the input laser beam or of the at least one pulsed laser beam provided by means of the laser beam source are emitted chronologically offset and/or corrected such that they strike target material arranged in the target area in the first operating mode and chronological irregularities upon the coupling of the target material into the target area are compensated for.

In particular, the laser beam source is configured to provide laser pulses of the pulsed input laser beam and/or of the pulsed laser beam having a constant energy mean value, wherein an energy of the laser pulses in operation of the laser system deviates from the energy mean value by less than 2% and in particular by less than 1%. The energy mean value is to be understood in particular as a specified setpoint value of the energy of the laser pulses.

In particular, the laser beam source is configured to provide laser pulses of the pulsed input laser beam and/or of the pulsed laser beam having a constant pulse repetition rate mean value, wherein a pulse repetition rate of the provided laser pulses in operation of the laser system deviates from the constant pulse repetition rate mean value by less than 20% and in particular by less than 15%. In particular, the chronological corrections, which can be required for the above-mentioned synchronization of laser pulses with the target material, can take place in the scope of these deviations. The pulse repetition rate mean value is to be understood in particular as a constant setpoint value of the pulse repetition rate, from which it is possible to deviate accordingly for the mentioned synchronization of the laser pulses.

In particular, the laser system comprises a feed unit for feeding target material into the target area. For example, the target material is in each case introduced into the target area by means of the feed unit in the form of individual units and/or droplets. In particular, the target material is then fed so that it is positioned in the target area at an (erroneous) time or within a time window. In principle, it is also possible that the target material is introduced into the target area by means of the feed unit in the form of a material flow and in particular a continuous material flow.

In particular, it can be provided that the feed unit is configured to introduce the target material into the target area at a speed of at least 50 m/s and/or at most 200 m/s and preferably at least 60 m/s and/or at most 130 m/s. The target material can in particular pass through the target area at a speed in the mentioned ranges.

In particular, it can be provided that the target material is introduced into the target area in operation of the laser system with an at least approximately constant speed and/or with an at least approximately constant cycle rate.

In particular, the target material passes through the target area with a movement direction oriented at least approximately in parallel to the direction of gravity.

It can be favourable if the laser system comprises a target material detection unit for detecting target material within the target area, wherein the target material detection unit is in particular configured, upon detection of target material in the target area, to emit a control signal to the laser beam source and/or to the control unit assigned to the beam deflection unit. In particular in the first operating mode, a chronological synchronization of laser pulses of the pulsed laser beam with the target material arranged in the target area can thus be implemented. Furthermore, depending on the application, the first or second operating mode can then be selected based on a presence of target material in the target area.

It can be advantageous if the laser system has a beam detection unit for detecting an orientation and/or a position of pulsed laser beams emerging from the beam deflection unit. In particular the position of the at least one pulsed laser beam can thus be regulated. For example, a stabilization of the orientation and/or position of the at least one pulsed laser beam can be executed by means of the beam detection unit. The laser system can have a corresponding unit for stabilizing orientation and/or position for this purpose. Furthermore, the position of the at least one pulsed laser beam can thus be regulated in the first operating mode and/or the second operating mode by means of the control unit assigned to the beam deflection unit.

According to embodiments of the invention, a method for providing a pulsed laser beam intended for interaction with a target material is provided, in which the target material will be arranged or is arranged in a target area, a pulsed input laser beam is provided by means of a laser beam source, the pulsed input laser beam is coupled into a beam deflection unit, wherein the pulsed input laser beam can be deflected and/or split by means of the beam deflection unit and at least one pulsed laser beam emerging from the beam deflection unit is provided by means of the beam deflection unit based on the pulsed input laser beam, wherein a position of the pulsed laser beam emerging from the beam deflection unit relative to the target area is controlled and/or regulated by actuating the beam deflection unit by means of a control unit, wherein the control unit has a first operating mode, in which the position of the at least one pulsed laser beam is selected so that it is directed onto the target area and interacts with the target material arranged in the target area, and wherein the control unit has a second operating mode, in which the position of the at least one pulsed laser beam is selected so that it misses the target area.

The method according to embodiments of the invention has one or more further features and/or advantages of the laser system according to embodiments of the invention. Advantageous embodiments have already been explained in conjunction with the laser system.

The method according to embodiments of the invention can be carried out in particular by means of the laser system according to embodiments of the invention. In particular, the method according to embodiments of the invention is carried out by means of the laser system according to embodiments of the invention.

A laser system for providing a laser beam having a focus zone, which has a non-rotationally symmetrical cross section, comprises a beam deflection unit, a control unit assigned to the beam deflection unit, and a laser beam source for providing an input laser beam for coupling into the beam deflection unit, wherein the beam deflection unit comprises an acoustooptical deflector and/or an acoustooptical modulator and wherein the control unit is configured to actuate the beam deflection unit such that the input laser beam is split by means of the beam deflection unit simultaneously into at least two laser beams emerging from the beam deflection unit and respective beam cross sections of the emerging laser beams overlap at least in some sections such that a focus zone having a non-rotationally symmetrical cross section is formed.

In particular, the laser beams emerging from the beam deflection unit are focused by means of a focusing optical unit, wherein the emerging laser beams overlap at least in some sections in a focal plane assigned to the focusing optical unit in order to form the focus zone having a non-rotationally symmetrical cross section there.

A non-rotationally symmetrical cross section is to be understood in particular as an elliptical cross section and/or an elongated cross section and/or a cross section having a preferred direction and/or a non-point symmetrical cross section.

In particular, the beam deflection unit is actuated by means of the control unit using a control voltage, which has a superposition and/or beat of signals having two or more frequencies.

A focus zone is to be understood in particular as a spatially contiguous radiation area, in which a radiation intensity is above a defined threshold intensity.

In a method for providing a laser beam having a focus zone, which has a non-rotationally symmetrical cross section, an input laser beam is provided by means of a laser beam source and the input laser beam is coupled into a beam deflection unit, wherein the beam deflection unit comprises an acoustooptical deflector and/or an acoustooptical modulator and wherein the control unit actuates the beam deflection unit such that the input laser beam is split by means of the beam deflection unit simultaneously into at least two laser beams emerging from the beam deflection unit and respective beam cross sections of the emerging laser beams overlap at least in some sections in the focus zone such that a focus zone having a non-rotationally symmetrical cross section is formed.

In particular, the specification “at least approximately” is generally to be understood as a deviation of at most 10%, i.e. an actual value deviates by at most 10% from an ideal value.

Exemplary embodiments are described below in conjunction with the drawings.

Identical or functionally equivalent elements are provided with the same reference signs in all figures.

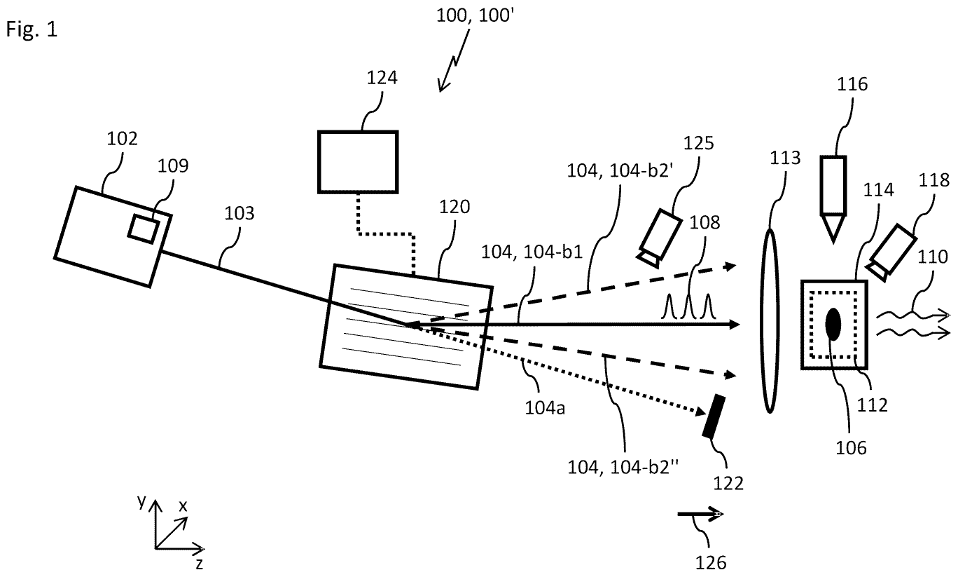

An exemplary embodiment of a laser system is shown in FIG. 1 and is designated therein with 100. The laser system 100 comprises a laser beam source 102, by means of which a pulsed input laser beam 103 is provided in operation of the laser system 100. It is provided that at least one pulsed laser beam 104 based on the input laser beam 103 is formed and this is directed onto a target material 106. Secondary radiation 110 can be generated by interaction of laser pulses 108 assigned to the input laser beam 103 or the pulsed laser beam 104 with the target material 106. Alternatively or additionally, the target material 106 can be prepared for generating secondary radiation by the interaction.

To generate secondary radiation, the laser beam source 102 can be designed, for example, as a CO₂ laser, which has an average power of 1 kW or more in operation of the laser system 100.

If the laser system 100 is to be used to prepare the target material 108, the laser beam source 102 can be designed, for example, as a Nd: YAG laser or Yb-YAG laser. The average power is in this case, for example, between 500 W and 800 W. The input laser beam 103 and/or pulsed laser beam 104 provided by means of the laser beam source 102 then has, for example, laser pulses 108 having a pulse repetition rate in the kilohertz range, for example, in the range between 40 kHz and 100 kHz. A respective pulse duration of the laser pulses 108 is in particular in the nanosecond range, for example in the range of 1 ns to 500 ns, in particular in the range of 5 ns to 20 ns.

In principle, the laser system 100 can have multiple laser beam sources 102, for example one for generating secondary radiation 110 and a further one for preparing the target material 108.

The laser beam source 102 can have, for example, a laser beam source control unit 109, by means of which an emission of laser pulses 108 by the laser beam source 102 can be triggered and/or controlled at certain times. For example, it can be provided that the laser beam source 102 emits one or more laser pulses 108 when the control unit 109 receives a corresponding control signal. Laser pulses 108 can thus be deliberately requested at specific times and/or laser pulses 108 regularly emitted by the laser beam source 102 can be chronologically offset in relation to one another. This can be implemented, for example, by means of pulse-on-demand concepts.

The secondary radiation 110 that can be provided by interaction of the target material 106 with the laser pulses 108 of the laser beam 104 is, for example, EUV radiation. For example, the target material 106 is or comprises tin.

The laser system 100 has a target area 112, in which the target material 106 is arrangeable in order to subject it to the laser beam 104. It is provided that in operation of the laser system 100, the target material 106 is introduced into the target area 112 and is caused to interact there with the laser pulses 108. In particular, the pulsed laser beam 104 directed onto the target material 106 is focused on the target material 106 and/or the target area 112. A focusing optical unit 113 can be provided for this purpose, for example.

In particular, it can be provided that the target area 112 is formed and/or positioned in a fluid-tight and/or gas-tight chamber 114. A vacuum is formed in the chamber 114, for example.

To feed the target material 106 to the target area 112, the laser system 100 can have a feed unit 116, by means of which an introduction of the target material 106 into the target area 112 can be controlled and/or regulated. For example, target material 106 can be delivered by means of the feed unit 116 such that it passes through the target area 112 at specific, in particular regular, times and/or is positioned in the target area 112 at specific, in particular regular, times.

For example, the target material 106 is introduced into the target area at a speed between 60 m/s and 120 m/s, wherein the target material 106 is provided in this case in particular in the form of individual droplets, which pass through the target area in succession.

With respect to the technical details relating to the coupling of target material 106 into the target area 112 to generate secondary radiation, reference is made to the scientific publication “Light sources for high-volume manufacturing EUV lithography: technology, performance, and power scaling”, I. Fomenkov et al., Advanced Optical Technologies 6 (3): 173-186, DOI: 10.1515/aot-2017-0029.

For example, target material 106 can be provided by means of the feed unit 116 in the form of individual elements and/or droplets, which each pass through the target area 112 in succession at specific times. In the example shown, the direction of gravity is oriented in the negative y direction, so that target material 106 delivered by means of the feed unit 116 passes through the target area 112 from top to bottom (i.e. in the negative y direction).

It can be provided that the laser system 100 has a target material detection unit 118, by means of which it is detectable whether a target material 106 is arranged in the target area 112 at a specific time. The target material detection unit 118 comprises, for example, a camera, in order to detect the target material 106 in the target area 112, for example by means of image recognition.

The laser system 100 comprises a beam deflection unit 120, into which the input laser beam 103 is coupled. The pulsed laser beams formed by means of the beam deflection unit 120 based on the input laser beam 103 and emerging from the beam deflection unit 120 are designated as pulsed laser beams 104.

The beam deflection unit 120 is capable of deflecting and/or splitting the input laser beam 103. Therefore, in principle one pulsed laser beam 104 or multiple pulsed laser beams 104 can emerge simultaneously from the beam deflection unit 120. An alignment and/or a position of the pulsed laser beam 104 or the pulsed laser beams 104 relative to the target area 112 are adjustable by means of the beam deflection unit 120.

In the exemplary embodiment according to FIG. 1, the beam deflection unit 120 is or comprises an acoustooptical modulator and/or an acoustooptical deflector. The pulsed laser beam 104 incident on the beam deflection unit 120 is split in the example shown by means of the beam deflection unit 120 into multiple partial beams of different orders of diffraction, wherein the first-order partial beam is used as the used laser beam or pulsed laser beam 104 for application to the target material 106. The first-order partial beam used typically has more than 90% of a beam intensity of the laser beam 104 originally incident on the beam deflection unit 120. The zero-order partial beam designated by 104a is, like the partial beams of further other orders, not used and is guided, for example, into a beam trap 122.

To actuate the beam deflection unit 120, the laser system 100 comprises a control unit 124, which is connected for signalling to the beam deflection unit 120 or is integrated into the beam deflection unit 120, for example. By actuating the beam deflection unit 120 by means of the control unit 124, the pulsed laser beam 104 can be displaced relative to the target area 112, i.e. the alignment and/or position of this beam relative to the target area 112 can be adjusted.

It can be provided that the laser system has a beam detection unit 125 (indicated in FIG. 1) for detecting an orientation and/or a position of pulsed laser beams 104 emerging from the beam deflection unit 120. The beam detection unit 125 comprises in particular multiple detectors and/or cameras, by means of which the orientation and/or position is detectable. For example, the beam detection unit 125 is or comprises a beam tracker.

In particular, a stabilization of the orientation and/or positioning of the pulsed laser beams 124 can be carried out by means of the beam detection unit 125. The laser system 100 can have for this purpose a unit (not shown) for stabilizing the orientation and/or positioning of the pulsed laser beams 124, which receives information with respect to the orientation and/or positioning of the pulsed laser beams 124 from the beam detection unit 125 and carries out the stabilization on the basis of this information.

Furthermore, the beam detection unit 125 can be connected for signalling to the control unit 124 in order to transmit information thereto with respect to the orientation and/or positioning of pulsed laser beams 104 emerging from the beam deflection unit 120. In particular, a regulation of the orientation and/or positioning of the pulsed laser beams 104 can thus be implemented by means of the control unit 124 or the beam deflection unit 120.

It is provided that the control unit 124 has a first operating mode, in which the beam deflection unit 120 is actuated such that the pulsed laser beam 104 emerging therefrom is directed onto the target area 112 and the laser pulses 108 strike the target area 112 and/or a target material 106 arranged therein. In this case, the laser pulses 108 of the pulsed laser beam 104 can interact with the target material 106 arranged in the target area 112.

The pulsed laser beam 104 decoupled from the beam deflection unit 120 in this first operating mode is additionally designated by 104-b1 in FIG. 1.

Furthermore, the control unit 124 has a second operating mode, in which the beam deflection unit 120 is actuated such that the pulsed laser beam 104 emerging therefrom misses the target area. In this case, the target area 112 and/or a target material 106 arranged therein are not struck or are nearly not struck by the laser pulses 108. In this case, the laser pulses 108 may not interact or may only slightly interact with the target material. In this case, depending on the application, no secondary radiation 110 is generated or generated secondary radiation 110 is only present below a threshold intensity, or no sufficient interaction for the preparation of the target material takes place.

In principle, there are a variety of options for how the pulsed laser beam 104 is deflected by means of the beam deflection unit 120 in order to miss the target area 112. In the second operating mode, multiple variants can therefore be provided with respect to the alignment and/or position of the pulsed laser beam 104 relative to the target area 112.

As indicated in FIG. 1, for example, two different variants can be provided, wherein in a first variant of the second operating mode, the pulsed laser beam 104 is deflected, for example, in a first direction in order to miss the target area 112 and the target material 106 located therein (pulsed laser beam 104-b2′) and in a second variant it is deflected in a second direction different from the first direction, in order to miss the target area 112 and the target material 106 located therein (pulsed laser beam 104-b2″). In principle, it is possible to provide further variants of the second operating mode, in which the pulsed laser beam 104 is deflected in different directions in order to miss the target area 112 and/or the target material 106.

If, for example, the target material 106 is fed into the target area 112 by means of the feed unit 116 from top to bottom (i.e. in the negative y direction), as shown in FIG. 1, the laser beam 104-b2′ is deflected spatially behind the target material 106 with respect to the movement direction of the target material 106 in order to miss it, i.e. the laser beam 104-b2′ is located behind the target material 106 when it is positioned in the target area 112. The laser beam 104-b2″ is deflected spatially in front of the target material 106 in order to miss it, i.e. the laser beam 104-b2″ is located in front of the target material 106 when it is positioned in the target area 112.

It is self-evident that the pulsed laser beam 104 could also be deflected, for example, in a direction oriented transversely or perpendicularly to the movement direction of the target material 106 in order to miss it. In principle, the pulsed laser beam 104 can be deflected for this purpose in any arbitrary direction which is oriented perpendicularly to its beam propagation direction 126.

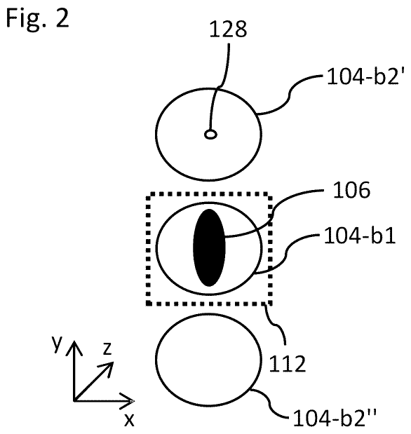

FIG. 2 shows the positioning of the pulsed laser beams 104-b1, 104-b2′, and 104-b2″ relative to the target area 112 and the target material 106 in a cross-sectional plane, which is oriented perpendicular to the beam propagation direction 126 of the pulsed laser beam 104-b1 incident on the target area 112 and is positioned at the target material 106 (in the example shown, the beam propagation direction 126 is oriented parallel to the z direction and the cross-sectional plane is oriented parallel to the x-y plane).

A respective beam cross section of the laser beams 104-b1, 104-b2′, and 104-b2″ is indicated by circles in FIG. 2. In particular, the laser beams 104-b1, 104-b2′, and 104-b2″ are focused at the height of the target area 112 and/or the target material 106 with respect to the beam propagation direction 126.

The pulsed laser beams 104-b2′ and 104-b2″ provided in the second operating mode preferably extend symmetrically with respect to a plane of symmetry. In particular, the pulsed laser beam 104-b1 formed in the first operating mode lies in this plane of symmetry (in the example shown in FIG. 1, the plane of symmetry is oriented parallel to the beam propagation direction 126 and/or parallel to the x-z plane).

In particular, the respective centre points 128 of the beam cross sections of the pulsed laser beams 104-b2′ and 104-b2″ are point symmetrical with respect to a position of the target material 106 and/or point symmetrical with respect to the centre point of the beam cross section of the pulsed laser beam 104-b1 formed in the first operating mode.

In a further variant of the second operating mode, it can be provided that the input laser beam 103 coupled into the beam deflection unit 120 is split by means of the beam deflection unit 120 simultaneously into two or more deflected partial beams. For example, the pulsed laser beam 104 is split by means of the beam deflection unit 120, as indicated in FIG. 1, into the two pulsed laser beams 104-b2′ and 104-b2″. These then each have, for example, approximately half the intensity of the pulsed laser beam 104-b1 formed in the first operating mode and directed onto the target area 112.

The actuation of the beam deflection unit 120, which is designed in the example shown as an acoustooptical modulator and/or acoustooptical deflector, is carried out by the control unit 124 by means of a control voltage. The control voltage has a defined frequency and/or a defined frequency spectrum. For example, the control voltage is or comprises a sinusoidal voltage.

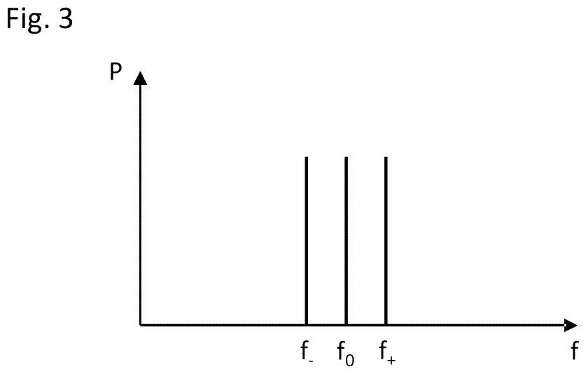

In the first operating mode, the actuation of the beam deflection unit 120 takes place with a specific carrier frequency f₀ (FIG. 3) in order to implement the laser beam 104-b1 striking the target material 106. The carrier frequency f₀ is, for example, 80 MHz.

In the second operating mode, the frequency of the voltage is increased or reduced in relation to the carrier frequency f₀ to implement the pulsed laser beams 104-b2′ and 104-b2″. For example, to implement the pulsed laser beam 104-b2′, the beam deflection unit 120 is actuated using a frequency f₋ reduced in relation to the carrier frequency f₀ and to implement the pulsed laser beam 104-b2″, the beam deflection unit 120 is actuated using a frequency f₊ increased in relation to the carrier frequency f₀.

For example, the reduced frequency f₋ and the increased frequency f₊ are symmetrically distributed around the carrier frequency f₀. The reduced frequency f₋ is, for example, 79 MHz and the increased frequency f₊ is, for example, 81 MHz.

In the case of the above-mentioned further variant of the second operating mode, in which the input laser beam 103 is simultaneously split into two or more deflected partial beams by means of the beam deflection unit 120, the beam deflection unit 120 is actuated by means of a voltage, the spectrum of which has two or more frequencies. For example, the voltage has a superposition and/or beat of signals having two or more frequencies.

For the simultaneous deflection of the incident pulsed laser beam 104 into the pulsed laser beam 104-b2′ and the pulsed laser beam 104-b2″, the beam deflection unit 120 is actuated by means of the control unit 124, for example, using a voltage which has a superposition of signals having the reduced frequency f₋ and the increased frequency f₊.

In an alternative embodiment of a laser system, which is designated hereinafter with 100′, this comprises the laser beam source 102, the beam deflection unit 120, the control unit 124, and in particular the focusing optical unit 113, wherein the beam deflection unit 120 is designed as an acoustooptical deflector and/or acoustooptical modulator. In this embodiment, the input laser beam 103, which is not necessarily a pulsed laser beam, is provided by means of the laser beam source 102.

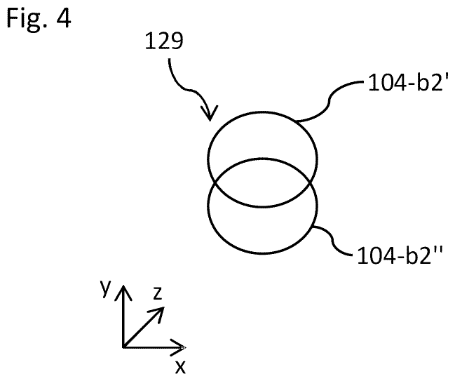

The beam deflection unit 120 is actuated by means of the control unit 124 using a voltage which has a superposition and/or a beat of two or more frequencies. The frequencies assigned to the voltage are selected so that the respective focused beam cross sections of the pulsed laser beams 104-b2′ and 104-b2″ formed overlap at least in some sections (FIG. 4). A focus zone 129 having a non-rotationally symmetrical cross section is thus formed (with respect to a cross-sectional plane oriented perpendicularly to the beam propagation direction 126). This can be relevant, for example, for applications in transparent material processing. For example, the focus zone has an elliptical cross section.

The laser system 100 functions as follows:

In operation of the laser system 100, the pulsed laser beam 104 is provided by means of the laser beam source 102 and the beam deflection unit 120. In order that secondary radiation 110 is generated and/or the target material 106 is prepared in order to be able to generate secondary radiation 110 using it, the pulsed laser beam 104 is caused to interact with the target material 106, i.e. the laser pulses 108 are applied to the target material 106.

For this purpose, the beam deflection unit 120 is actuated by means of the control unit 124 in the first operating mode so that in particular precisely one pulsed laser beam directed onto the target area 112 is generated, for example the pulsed laser beam 104-b1. The laser pulses 108 assigned to this laser beam 104-b1 are incident on the target area 112 and are introduced into the target area 112 such that they are chronologically synchronized with the target material 106 introduced into the target area 112. An interaction of one or more laser pulses 108 with the target material 106 located in the target area 112 thus takes place.

A presence of target material 106 in the target area 112 can be detected, for example, by means of the target material detection unit 118. For example, the target material detection unit 118, upon the presence of target material 106 in the target area, can emit a control signal to the laser beam source control unit 109, which then actuates the laser beam source 102 in order to emit laser pulses 108 at a specific time or to chronologically offset emitted laser pulses 108. An emission of laser pulses 108 at specified times can be implemented, for example, by means of pulse-on-demand methods. Irregularities in the coupling of the target material 106 into the target area 112 can thus be compensated for, for example, and it can be ensured that in the case of the first operating mode, a target material 106 located in the target area 112 in a specific time window is actually struck by the laser pulses 108 to generate secondary radiation 110 and/or to prepare for this.

In particular, the coupling of target material 106 into the target area 112 and the repetition rate of the laser pulses 108 can be matched to one another and/or synchronized with one another such that the target material 106 is struck by the laser pulses 108 in the first operating mode when it is positioned within a specific time window in the target area. Typically present (smaller) chronological irregularities in the coupling of the target material 106 into the target area 112 can be compensated for as described by a chronological offset of the laser pulses 108 emitted by the laser source 102.

In order to vary, for example, an intensity and/or a dose of the generated secondary radiation 110, it can be provided that an interaction of the laser pulses 108 with target material 106 arranged in the target area 112 is temporarily suppressed. As a result, for example, the intensity of the emitted secondary radiation 110 can be reduced in the chronological average.

For this purpose, the beam deflection unit 120 is actuated by means of the control unit 124 in the second operating mode, by which the pulsed laser beams 104-b2′ and/or 104-b2″ are formed, which miss the target area 112 and the target material 106. The respective laser pulses 108 of these pulsed laser beams 104-b2′, 104-b2″ do not contribute or do not significantly contribute to generating secondary radiation 110 or to preparing the target material 108.

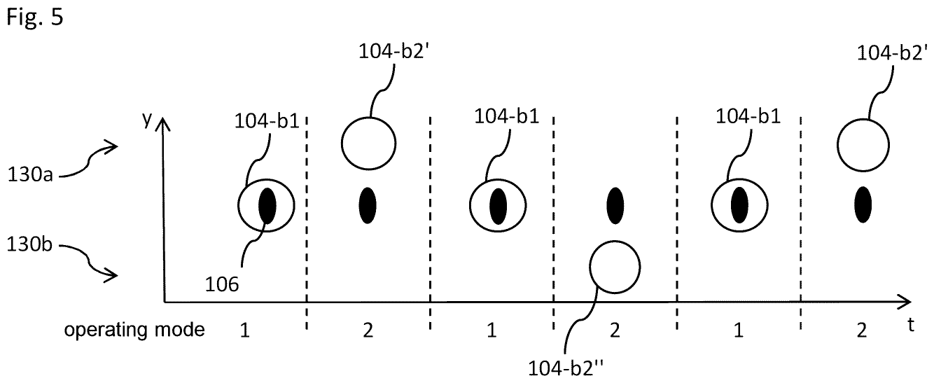

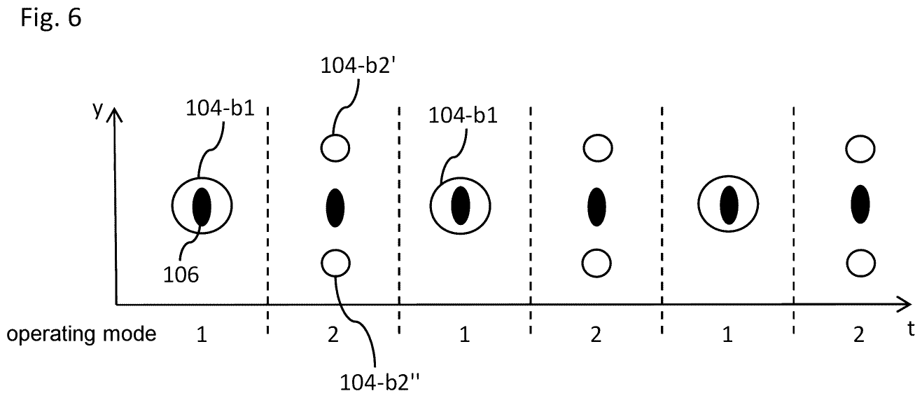

In the examples shown in FIGS. 5 and 6, the beam deflection unit 120 is actuated by means of the control unit 124 in chronological alternation in the first operating mode and in the second operating mode (FIGS. 5 and 6).

In the example according to FIG. 5, in chronologically successive second operating modes, the pulsed laser beam is alternately deflected toward different sides with respect to the target area 112 and/or the target material 106, i.e. the pulsed laser beams 104-b2′ and 104-b2″ are alternately formed in chronologically successive second operating modes. The pulsed laser beams 104-b2′ and 104-b2″ in the second operating mode are thus positioned in the example shown in the chronological average symmetrically with respect to the pulsed laser beam 104-b1 in the first operating mode.

For example, the pulsed laser beams 104-b2′ and 104-b2″ in the second operating mode are deflected in the example shown in FIG. 5 with respect to a position of the target area 112 and/or the target material 106 alternately toward a first side 130a and toward a second side 130b opposite to the first side 130a.

Alternatively thereto, in the example according to FIG. 6, the pulsed laser beam is split in the second operating mode simultaneously into the two pulsed laser beams 104-b2′ and 104-b2″. These simultaneously formed laser beams 104-b2′ and 104-b2″ are symmetrically positioned with respect to the pulsed laser beam 104-b1 in the first operating mode.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCE SIGNS

f₀ carrier frequency

f₋ reduced frequency

f₊ increased frequency

100, 100′ laser system

102 laser beam source

103 pulsed input laser beam

104 pulsed laser beam

104-b1 pulsed laser beam (first operating mode)

104-b2′ pulsed laser beam (second operating mode)

104-b2″ pulsed laser beam (second operating mode)

104a zero-order partial beam

106 target material

108 laser pulse

109 laser beam source control unit

110 secondary radiation

112 target area

113 focusing optical unit

114 chamber

116 feed unit

118 target material detection unit

120 beam deflection unit

122 beam trap

124 control unit

125 beam detection unit

126 beam propagation direction

128 centre point

129 focus zone

130a first side

130b second side

1. A laser system for providing a pulsed laser beam intended for interaction with a target material, the laser system comprising:
a beam deflection unit,
a control unit assigned to the beam deflection unit,
a laser beam source for providing a pulsed input laser beam for coupling into the beam deflection unit, and
a target area for arranging the target material,
wherein the pulsed input laser beam is capable of being deflected and/or split by the beam deflection unit, and at least one pulsed laser beam emerging from the beam deflection unit is provided by the beam deflection unit based on the pulsed input laser beam,
wherein the control unit is configured to control and/or regulate a position of the at least one pulsed laser beam relative to the target area by actuating the beam deflection unit, wherein the control unit has a first operating mode, in which the position of the at least one pulsed laser beam is selected so that the at least one pulsed laser beam is directed onto the target area, in order to interact with the target material arranged in the target area, and wherein the control unit has a second operating mode, in which the position of the at least one pulsed laser beam is selected so that the at least one pulsed laser beam misses the target area, wherein pulsed laser beams provided in the second operating mode are positioned symmetrically in a chronological and/or spatial average with respect to the pulsed laser beams formed in the first operating mode.

2. The laser system according to claim 1, wherein in the first operating mode, precisely one pulsed laser beam emerging from the beam deflection unit is provided, which is directed onto the target area and/or the target material.

3. The laser system according to claim 1, wherein in the second operating mode, precisely one pulsed laser beam emerging from the beam deflection unit is provided, which misses the target area.

4. The laser system according to claim 3, wherein the position of the precisely one pulsed laser beam is deflected, in chronologically successive second operating modes, alternately with respect to the target area toward a first side and toward a second side opposite to the first side, and/or is deflected alternately with respect to the target area in a first direction and in a second direction opposite to the first direction.

5. The laser system according to claim 1, wherein in the second operating mode, two or more pulsed laser beams emerging from the beam deflection unit are provided, which emerge simultaneously from the beam deflection unit.

6. The laser system according to claim 1, wherein the beam deflection unit comprises an acoustooptical deflector and/or an acoustooptical modulator.

7. The laser system according to claim 1, wherein the beam deflection unit is actuated by the control unit in the first operating mode using a first control voltage which has a constant carrier frequency.

8. The laser system according to claim 7, wherein the beam deflection unit is actuated by the control unit in the second operating mode using a second control voltage which has a frequency reduced in relation to the carrier frequency or increased in relation to the carrier frequency.

9. The laser system according to claim 7, wherein the beam deflection unit is actuated by the control unit in the second operating mode using a second control voltage which has a superposition of two or more frequencies, wherein the two or more frequencies are different from the carrier frequency.

10. The laser system according to claim 7, wherein the beam deflection unit is actuated by the control unit in the second operating mode using a second control voltage which has a beat of signals having a first frequency reduced in relation to the carrier frequency and a second frequency increased in relation to the carrier frequency.

11. The laser system according to claim 1, wherein in the first operating mode, laser pulses of the at least one pulsed laser beam are introduced into the target area such that the laser pulses are chronologically synchronized with the target material introduced into the target area, so that, in the first operating mode, an interaction of one or more laser pulses with the target material takes place in the target area.

12. The laser system according to claim 1, wherein the laser beam source is configured to provide laser pulses of the pulsed input laser beam and/or of the at least one pulsed laser beam having a constant energy mean value, wherein an energy of the laser pulses in operation of the laser system deviates from the energy mean value by less than 2%, and/or the laser beam source is configured to provide the laser pulses of the pulsed input laser beam and/or of the at least one pulsed laser beam having a constant pulse repetition rate mean value, wherein a pulse repetition rate of the provided laser pulses in operation of the laser system deviates from the constant pulse repetition rate mean value by less than 20%.

13. The laser system according to claim 1, further comprising a feed unit for feeding the target material into the target area, wherein the feed unit is configured to introduce the target material into the target area at a speed of at least 50 m/s and/or at most 200 m/s.

14. The laser system according to claim 1, further comprising:
a target material detection unit for detecting the target material within the target area, wherein the target material detection unit is configured, upon detection of the target material in the target area, to emit a control signal to the laser beam source and/or to the control unit assigned to the beam deflection unit, and/or
a beam detection unit for detecting an orientation and/or the position of the pulsed laser beams emerging from the beam deflection unit.

15. A method for providing a pulsed laser beam intended for interaction with a target material, the method comprising:
arranging the target material in a target area,
providing a pulsed input laser beam by using a laser beam source,
coupling the pulsed input laser beam into a beam deflection unit, wherein the pulsed input laser beam is capable of being deflected and/or split by the beam deflection unit, and at least one pulsed laser beam emerging from the beam deflection unit is provided by the beam deflection unit based on the pulsed input laser beam, and
controlling or regulating a position of the at least one pulsed laser beam emerging from the beam deflection unit relative to the target area by actuating the beam deflection unit by using a control unit, wherein the control unit has a first operating mode, in which the position of the at least one pulsed laser beam is selected so that the at least one pulsed laser beam is directed onto the target area and interacts with the target material arranged in the target area, and wherein the control unit has a second operating mode, in which the position of the at least one pulsed laser beam is selected so that the at least one pulsed laser beam misses the target area, wherein pulsed laser beams provided in the second operating mode are positioned symmetrically in a chronological and/or spatial average with respect to the pulsed laser beams formed in the first operating mode.
